(19) United States
(12) Patent Application Publication
(10) Pub. No.: US 2009/0283784 A1
(43) Pub. Date: Nov. 19, 2009

(54) SIDE-VIEW LIGHT EMITTING DIODE

(75) Inventor: CHIA-SHOU CHANG, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: Foxconn Technology Co., Ltd., Tu-Cheng (TW)

(21) Appl. No.: 12/202,398

(22) Filed: Sep. 1, 2008

(30) Foreign Application Priority Data
May 16, 2008 (CN) 200810067261.X

(51) Int. Cl. H01L 33/00

(52) U.S. Cl. 257/98; 257/99; 257/E33.072; 257/E33.058

(57) ABSTRACT

An exemplary side-view light emitting diode (LED) includes a substrate, a housing, a LED chip, a capsulation material and a reflecting layer. The housing and the substrate cooperatively form a receiving space therebetween. The LED chip is received in the receiving space and electrically connected with the substrate. The capsulation material is filled in the receiving space and encapsulates the LED chip in the housing. An indent is defined in a top portion of the capsulation material to cave a top surface of the capsulation material. The reflecting layer is spread on the top surface of the capsulation material. The light emitted from the LED chip upwardly towards the top surface of the capsulation material is reflected to a lateral side of the housing by the reflecting layer. The indent has a horizontal section with a size decreased along a top-to-bottom direction. The housing has a diameter gradually increased along the top-to-bottom direction.

### BACKGROUND

1. Technical Field

The present invention relates to light emitting diodes, and particularly to a side-view light emitting diode.

2. Description of Related Art

Presently, LEDs (light emitting diodes) are preferred to be used in the non-emissive display devices instead of CCFLs (cold cathode fluorescent lamp) due to the high brightness, long life-span, and wide color gamut of the LEDs.

A related side-view light emitting diode (LED) includes a substrate, a housing disposed on the substrate, a LED chip disposed on the substrate and in the housing, an electrode located on the substrate, a gold wire electrically connecting the LED chip with the electrode, and a capsulation material filled in the housing for encapsulating the LED chip, the electrode and the gold wire in the housing.

For obtaining the side-view LED which emits most of light from a lateral side thereof, the LED chip is lain down. Thus, a main part of the light emitted by the LED chip can directly shoot towards the lateral side of the housing and leaves the housing from the lateral side. However, the other part of the light emitted by the LED chip shoots towards a top surface of the capsulation material, which induces some light to leave the side-view LED from the top surface of the capsulation material and decreases the extracting rate of the light from the lateral side of the side-view LED.

What is need, therefore, is a side-view LED which can improve the drawbacks of the related side-view LED.

### SUMMARY

The present invention relates to a side-view light emitting diode. According to an exemplary embodiment of the present invention, the side-view light emitting diode includes a substrate, a light permeable housing, a light emitting diode chip, a light permeable capsulation material, an indent defined in a top portion of the capsulation material and a reflecting layer. The housing is disposed on the substrate. The housing and the substrate cooperatively form a receiving space therebetween. The light emitting diode chip is received in the receiving space and electrically connected with the substrate. The capsulation material is filled in the receiving space and encapsulates the light emitting diode chip in the housing. The indent caves a top surface of the capsulation material. The reflecting layer is spread on the top surface of the capsulation material. The light emitted from the light emitting diode chip upwardly towards the top surface of the capsulation material is reflected to a lateral side of the housing by the reflecting layer. From the lateral side of the housing, the reflected light leaves the side-view light emitting diode. The indent consists of a plurality of annular grooves along a top-to-bottom direction of the LED. Diameters of the annular grooves are decreased along the top-to-bottom direction, wherein each of the annular grooves is defined at least by an inclined sidewall. Horizontal, planar stepping surfaces are located between the annular grooves.

Other advantages and novel features of the present invention will become more apparent from the following detailed description of embodiment when taken in conjunction with the accompanying drawings.

### BRIEF DESCRIPTION OF THE DRAWINGS

FIG. 1 is an assembled, isometric view showing a side-view light emitting diode in accordance with a first exemplary embodiment of the present invention.

FIG. 2 is a cross-sectional view of the side-view light emitting diode of FIG. 1.

FIG. 3 is a cross-sectional view of a side-view light emitting diode in accordance with a second exemplary embodiment of the present invention.

FIG. 4 is a cross-sectional view of a side-view light emitting diode in accordance with a third exemplary embodiment of the present invention.

### DETAILED DESCRIPTION OF THE EMBODIMENTS

Reference will now be made to the drawings to describe the various present embodiments in detail.

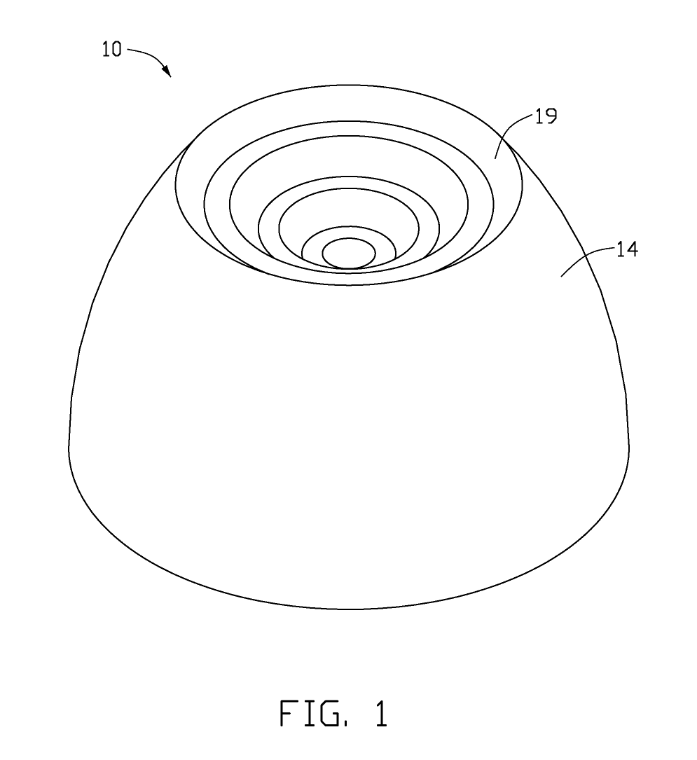

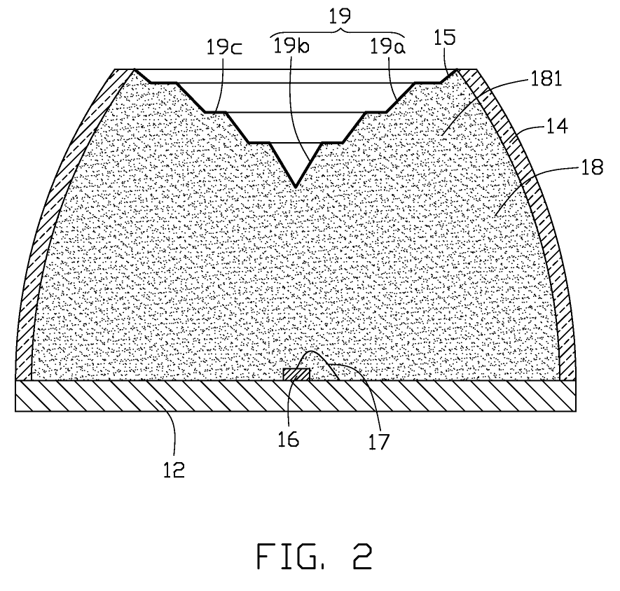

Referring to FIGS. 1-2, a side-view light emitting diode (LED) 10 according to a first exemplary embodiment of the present invention includes a substrate 12, a housing 14, a reflecting layer 15, a LED chip 16 and a capsulation material 18.

The substrate 12 is made of materials having electric and thermal conductivities. In this embodiment, the substrate 12 is made of metal such as aluminum, or copper. Alternatively, the substrate 12 can be made of ceramic.

The housing 14 is made of transparent, light permeable materials, such as epoxy resin, glass, etc. A horizontal section of the housing 14 has an annular shape, and a vertical section of the housing 14 is substantially a frustum with top and bottom ends of the housing 14 being open. A lateral side of the housing 14 is arc shaped. A diameter of the housing 14 gradually decreases from the bottom end toward the top end thereof. The housing 14 is located on the substrate 12, thereby forming a receiving space (not labeled) between the substrate 12 and the housing 14. A plurality of bulge points (not shown) are preferably formed on the lateral side of the housing 14 compactly, which enables the lateral side of the housing 14 to have a coarse surface so as to increase an extracting rate of the light from the lateral side of the housing 14. Alternatively, a plurality of tiny indents (not shown) can be formed on the lateral side of the housing 14 to coarsen the lateral side of the housing 14, thus also to increase the extracting rate of the light from the lateral side of the housing 14.

The LED chip 16 has a substantially rectangular shape. The LED chip 16 is disposed in the receiving space formed between the substrate 12 and the housing 14, and is adhered to the substrate 12 via silver colloid. The LED chip 16 is electrically connected to the substrate 12 via a gold wire 17. The substrate 12 electrically connects with an external power supply (not shown) via pins (not shown) extending outwardly from the substrate 12, so that the LED chip 16 can electrically connect with the power supply.

The capsulation material 18 is made of light permeable material, such as glass, epoxy resin, etc. The capsulation material 18 is filled in the receiving space and has a configuration matched with the housing 14. The capsulation material 18 encapsulates the LED chip 16 and the gold wire 17 in the receiving space.

An indent 19 is defined in a top portion 181 of the capsulation material 18 so as to cave a top surface of capsulation material 19. The indent 19 in whole has a substantially inverted, tapered configuration. The indent 19 of the capsulation material 18 includes four grooves, i.e. three upper grooves 19a and a lowest groove 19b, being arranged along a top-to-bottom direction of the top portion 181 of the capsulation material 18. Each of the upper grooves 19a is defined by an inclined sidewall (not labeled) and a planar stepping surface 19c below the inclined wall. The planar stepping surface 19c is horizontally extended. The lowest groove 19b has a configuration of an inverted cone, and each of the three upper grooves 19a has a configuration of an inverted frustum. A downward extension of each of the inclined sidewalls defining the upper grooves 19a forms a bottom tip coincidental with a central line of the capsulation material 18. The bottom tip of the lowest groove 19b is also coincidental with the central line of the capsulation material 18. A diameter of each of the grooves 19a, 19b gradually decreases along a top-to-bottom direction of each groove 19a, 19b. A diameter of the topmost end of an upmost groove 19b equals to the diameter of a topmost end of the housing 14. A diameter of a bottommost end of each of the upper grooves 19a is greater than the diameter of the topmost end of a neighboring groove 19a, 19b therebelow. The planar stepping surface 19c is located between two neighboring ones of the grooves 19a, 19b. The planar stepping surface 19c has an annular configuration. The stepping surface 19c interconnects the bottommost end of each of the upper grooves 19a with the topmost end of a neighboring one of the grooves 19a, 19b therebelow, and is parallel to the substrate 12.

The reflecting layer 15 is formed on the top surface of the capsulation material 18, i.e., the sidewalls of the grooves 19a, 19b and the stepping surfaces 19c of the upper grooves 19a, for reflecting the light emitted from the LED chip 16 towards a side surface of the capsulation material 18 and the lateral side of the housing 14. The material of the reflecting layer 15 is selected from a group of metals consisting of aluminum, silver, etc. The reflecting layer 15 is fully spread on the top surface of the capsulation material 18 by spraying process, evaporation process or sputtering process.

In operation of the present side-view LED 10, one part of the light emitted from the LED chip 16 directly shoot towards the side surface of the capsulation material 18 and the lateral side of the housing 14, and leaves the side-view LED 10 therefrom. The other part of the light emitted from the LED chip 16 firstly shoot toward the top surface of the capsulation material 18, and is reflected by the reflecting layer 15 towards the side surface of the capsulation material 18 and the lateral side of the housing 14, and finally leaves the side-view LED 10 therefrom.

In the present side-view LED 10, the lateral side of the housing 14 is curved and the lateral side of the housing 14 viewed from the vertical section forms an acute angle with the substrate 12. Thus, the incident angle of the light, which shoots towards the lateral side of the housing 18, is decreased. As a result, total internal reflection of the light which incidents on the lateral side of the housing 14 is reduced, and accordingly the extracting rate of the light from the lateral side of the housing 14 is increased. That is to say that the light from the side of the side-view LED 10 is increased. Moreover, by the indent 19 caved the top surface of the capsulation material 18 and the reflecting layer 15 spread on the top surface of the capsulation material 18, more light is reflected towards the side surface of the capsulation 18 and the lateral side of the housing 14, as compared to the related side-view LED, which further increases the extracting rate of the light from the side surface of the capsulation 18 and the lateral side of the housing 14. In addition, the coarse lateral side of the housing 14 further increases the extracting rate of the light from the side of the side-view LED 10.

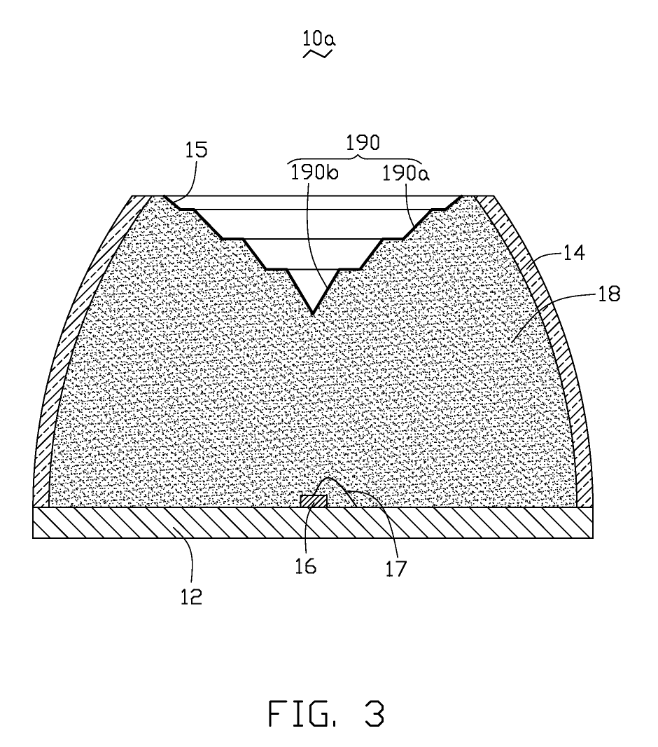

FIG. 3 shows a second embodiment of the side-view LED 10a. Except for the indent 190, other parts of the side-view LED 10a in accordance with this second embodiment have substantially the same configurations as the side-view LED 10 of the previous first embodiment. More specifically, the indent 190 in this second embodiment includes four grooves, i.e., three upper grooves 190a and a lowest groove 190b, arranged along the top-to-bottom direction, and the diameter of the topmost end of the upmost groove 190a is smaller than the diameter of the topmost end of the housing 14.

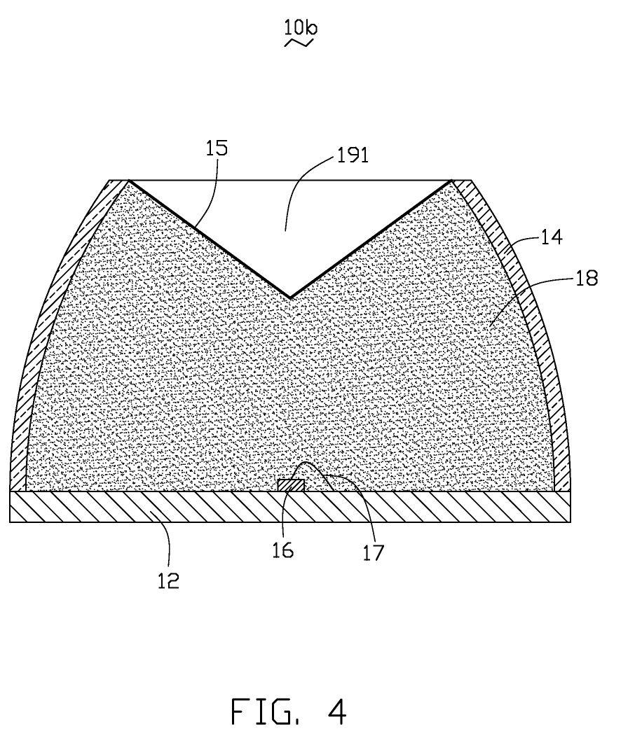

FIG. 4 shows a third embodiment of the side-view LED 10b. The difference between the third embodiment and the previous first and the second embodiments is that the indent 191 defined in the top portion 181 of the capsulation material 18 has a configuration of a single inverted cone.

The indents 19, 190, 191 disclosed in the first, the second and the third embodiments each have a round cross section at the horizontal plane. Alternatively, the cross section of each of the indents 19, 190, 191 can be varied. For example, the cross section of each of the indents 19, 190, 191 can be triangular, rectangular, etc.

It is to be understood, however, that even though numerous characteristics and advantages of the present invention have been set forth in the foregoing description, together with details of the structure and function of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A side-view light emitting diode comprising:
a substrate;
a light permeable housing disposed on the substrate, the housing and the substrate cooperatively forming a receiving space therebetween;
a light emitting diode chip received in the receiving space and electrically connected with the substrate;
a light permeable capsulation material filled in the receiving space and encapsulating the light emitting diode chip in the housing;
an indent defined in a top portion of the capsulation material to cave a top surface of the capsulation material; and
a reflecting layer spread on the top surface of the capsulation material;
wherein light emitted from the light emitting diode chip upwardly towards the top surface of the capsulation material is reflected to a lateral side of the housing by the reflecting layer, and from the lateral side of the housing, the light leaves the side-view light emitting diode.

2. The side-view light emitting diode of claim 1, wherein the housing is a hollow frustum with the lateral side being arced and top and bottom ends thereof being open.

3. The side-view light emitting diode of claim 2, wherein a side surface of the housing is a coarse surface.

4. The side-view light emitting diode of claim 2, wherein a diameter of the housing decreases from the bottom end of the housing towards the top end of the housing.

5. The side-view light emitting diode of claim 1, wherein the indent is caved downwardly from the top surface of capsulation material.

6. The side-view light emitting diode of claim 1, wherein the indent in whole has a substantially inverted, tapered configuration.

7. The side-view light emitting diode of claim 6, wherein the indent comprises a plurality of grooves arranged along a top-to-bottom direction of the top portion of the capsulation material, each of the grooves extends along a circumferential direction of the capsulation material, and a diameter of each of the grooves gradually increases from a bottom end of the each of the grooves towards a top end of the each of the grooves.

8. The side-view light emitting diode of claim 7, wherein the diameter of a bottommost end of the each of the grooves is larger than the diameter of a topmost end of a neighboring lower groove, and a stepping surface is formed between two neighboring grooves.

9. The side-view light emitting diode of claim 7, wherein a lowest groove has a configuration of an inverted cone, and each of the other upper grooves has a configuration of an inverted frustum.

10. The side-view light emitting diode of claim 7, wherein a diameter of a topmost end of an upmost groove equals to a diameter of a topmost end of the housing.

11. The side-view light emitting diode of claim 7, wherein a diameter of a topmost end of an upmost groove smaller than a diameter of a topmost end of the housing.

12. The side-view light emitting diode of claim 6, wherein a horizontal section of the indent has one of an annular shape, a triangular shape, a rectangular shape.

13. The side-view light emitting diode of claim 6, wherein a diameter the indent is gradually increased from a bottom end of the indent towards a top end of the indent.

14. The side-view light emitting diode of claim 1, wherein the indent has a configuration of a single inverted cone.
